(19) United States
(12) Patent Application Publication
(10) Pub. No.: US 2001/0026498 A1
(43) Pub. Date: Oct. 4, 2001

(54) Memory configuration having a circuit for determining the activated memory array

(76) Inventors: Stefan Dietrich, Turkenfeld (DE); Peter Schrogmeier, Munchen (DE); Sabine Schoniger, Hausham (DE); Christian Weis, Munchen (DE)

Correspondence Address: LERNER AND GREENBRG, P.A., POST OFFICE BOX 2480, HOLLYWOOD, FL, 33022-2480, US

(21) Appl. No.: 09/826,216

(22) Filed: Apr. 4, 2001

(30) Foreign Application Priority Data
Apr. 4, 2000 (DE) 100 16 720.9

(51) Int. Cl. G11C 8/00

(52) U.S. Cl. 365/230.03

(57) ABSTRACT

The invention describes a memory configuration having a matrix memory in which an evaluation circuit is provided which, when selecting column lines, takes into account which physical row line is being driven.

### BACKGROUND OF THE INVENTION

Field of the Invention

The invention relates to a memory configuration having a matrix memory and to a method for repairing the memory configuration. Memory configurations having a matrix memory are used, in particular, in semiconductor memories. The matrix memory has a plurality of memory arrays which are in turn subdivided into individual memory cells. Each memory cell is connected to a column line and to a row line which can be used to address each memory cell uniquely. To address the memory cells, a row decoder and a column decoder are provided for enabling a line connection for inputting or outputting data into or from the memory cell. The column decoder is for ascertaining the physical column line from a supplied column address, and the row decoder is for ascertaining the physical row line from a supplied row address for the memory cell which is to be addressed.

For a plurality of memory arrays, a single column line is always activated at the same time in order to read in or read out data from memory cells. If a column line is faulty, the column line is repaired by a replacement column line provided in the matrix memory. In this context, the column address of the faulty column line is assigned the address of the replacement column line in the column decoder. Similarly, if a row line is faulty, a replacement row line is selected and the address of the faulty row line is assigned to the address of the replacement row line in the row decoder. If the number of replacement row lines in one memory array is not sufficient, then a replacement row line from another memory array is chosen.

This presents the problem that the address of the row line is not related to the physical memory array containing the actually addressed row line. Usually, the applied row address is used to stipulate the memory array which is meant to contain the actual physical row line.

### SUMMARY OF THE INVENTION

It is accordingly an object of the invention to provide a method for repairing a memory configuration which overcomes the above-mentioned disadvantageous of the prior art apparatus and methods of this general type. In particular, it is an object of the invention to provide a method for repairing a memory configuration that takes account of the physical position of the addressed row line for the selection of the column line.

With the foregoing and other objects in view there is provided, in accordance with the invention, a memory configuration including a matrix memory that is subdivided into a plurality of memory arrays. The matrix memory has a plurality of column lines and a plurality of row lines. At least one of the plurality of the column lines is routed through at least two of the plurality of the memory arrays. The plurality of the memory arrays have a plurality of memory cells. A respective one of the plurality of the memory cells is accessible via one of the plurality of the column lines and one of the plurality of the row lines in order to write or read data. Each one of the plurality of the memory cells is provided with an address that can be used to access that one of the plurality of the memory cells. The address includes a column address and a row address. A column decoder is provided for ascertaining a physical column line from the column address. A row decoder is provided for ascertaining a physical row line from the row address. An evaluation circuit is connected to the plurality of the row lines. The evaluation circuit uses signals that are present on the plurality of the row lines for ascertaining which one of the plurality of the memory arrays contains an addressed one of the plurality of the row lines. The column decoder is connected to the evaluation circuit. The column decoder is configured for selecting one of the plurality of the column lines by taking into account the one of the plurality of the memory arrays that contains the addressed one of the plurality of the row lines.

Preferably, an evaluation circuit is provided which is connected to the physical row lines. The evaluation circuit uses the signals which are present on the physical row lines to ascertain which memory array contains the driven row line. The information about the ascertained memory array is taken into account for the selection of the physical column line. The effect achieved by this is that a column line can be uniquely assigned to a plurality of memory arrays even though a row line in one memory array has been repaired by a row line in another memory array.

In accordance with an added feature of the invention, a selection circuit is provided which drives different column lines in the column decoder on the basis of the memory array in which the addressed row line is physically located. The use of a selection circuit permits the invention to be implemented in a simple manner.

In accordance with an additional feature of the invention, the selection circuit assigns different column addresses to one and the same redundant column line on the basis of the memory array containing the addressed row line.

In accordance with another feature of the invention, the column decoder uses a single row address to drive a respective row line from two different memory arrays at the same time. This reduces the circuit complexity for driving.

In accordance with a further feature of the invention, the column decoder is preferably connected to at least two memory arrays by a single column line. This also reduces the circuit complexity for driving a plurality of memory arrays.

In accordance with a further added feature of the invention, the selection circuit is stipulated only when the operability of the memory configuration is checked, in order to repair two column lines, such that the selection circuit is connected to at least two selected replacement column lines.

The use of the selection circuit to repair a memory configuration provides the advantage that a replacement column line can be assigned to memory cells in a plurality of memory arrays. In this way, efficient utilization of the available replacement column lines is achieved.

With the foregoing and other objects in view there is provided, in accordance with the invention, 6. A method for repairing a memory configuration, that includes: providing a matrix memory that is subdivided into a plurality of memory arrays; providing the matrix memory with a plurality of column lines and a plurality of row lines; routing at least one of the plurality of the column lines through at least two of the plurality of the memory arrays; providing the plurality of the memory arrays with a plurality of memory cells such that a respective one of the plurality of the memory cells is accessible via one of the plurality of the column lines and one of the plurality of the row lines in order to write or read data; providing each one of the plurality of the memory cells with an address that can be used to access the one of the plurality of the memory cells; providing the address with a column address and a row address; providing a column decoder for ascertaining a physical column line from the column address; providing a row decoder for ascertaining a physical row line from the row address; defining one of the plurality of the column lines as a replacement column line and defining one of the plurality of the column lines as a faulty column line; replacing the faulty column line with the replacement column line by assigning the replacement column line to the column address of the faulty column line in the column decoder; providing a selection circuit that connects the column decoder to the replacement column line; and configuring the selection circuit such that the replacement column line is chosen based on the one of the plurality of the row lines that is associated with the one of the plurality of the memory cells that is repaired by the replacement column line.

Other features which are considered as characteristic for the invention are set forth in the appended claims.

Although the invention is illustrated and described herein as embodied in a memory configuration having a circuit for determining the activated memory array, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 shows a schematic illustration of the design of a matrix memory; and

FIG. 2 shows the design of a column decoder.

### DESCRIPTION OF THE PREFERRED EMBODIMENTS

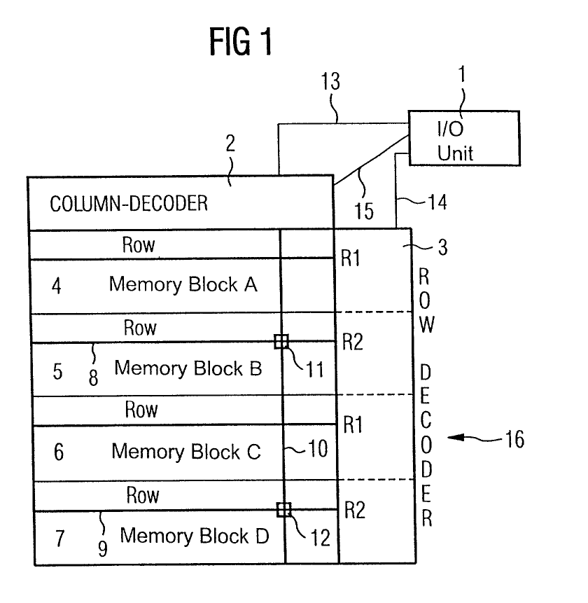

Referring now to the figures of the drawing in detail and first, particularly, to FIG. 1 thereof, there is shown a matrix memory 16 that includes a first memory array 4, a second memory array 5, a third memory array 6 and a fourth memory array 7. In addition, a column decoder 2 and a row decoder 3 are provided which are connected to the column lines 10 and the row lines 8, 9 of the memory arrays 4, 5, 6, 7. The column decoder 2 is connected to an input/output unit 1 by a first address line 13. In addition, the column decoder 2 is connected to the input/output unit 1 by an input/output line 15. The input/output unit 1 is also connected to the row decoder 3 by a second address line 14.

The row decoder 3 is designed such that a row line in the first memory array 4 and the third memory array 6 or a row line in the second memory array 5 and the fourth memory array 7 is activated in each case. In addition, the first memory array 4, the second memory array 5, the third memory array 6 and the fourth memory array 7 are each connected by a column line 10 at the same time. FIG. 1 shows a column line 10 which is routed through all four memory arrays 4, 5, 6, 7. At the same time, FIG. 1 shows that the first row lines R1 in the first and the third memory array 4, 6 are addressed at the same time. In another circuit example, the second row lines R2 in the second and the fourth memory array 5, 7 are addressed by the row decoder 3.

A memory array has a multiplicity of memory cells which can be uniquely driven using a column line 10 and a row line 8, 9. A first memory cell 11 can be addressed, by way of example, by the column line 10 and by the first row line 8. A second memory cell 12 can be addressed by the column line 10 and the second row line 9.

The input/output unit 1 passes a column address and a row address to the column decoder 2 and to the row decoder 3, respectively. The column decoder 2 uses the supplied column address to ascertain the physical column line 10 which needs to be driven. The row decoder 3 uses the supplied row address to ascertain the physical row line 8, 9 which needs to be driven.

By way of example, the input/output unit 1 prescribes the column address 10 and the row address 8 in order to access the first memory cell 11 via the column line 10 and the first row line 8, which means that data can be written to or read from the first memory cell 11. The data interchange takes place via the input/output line 15.

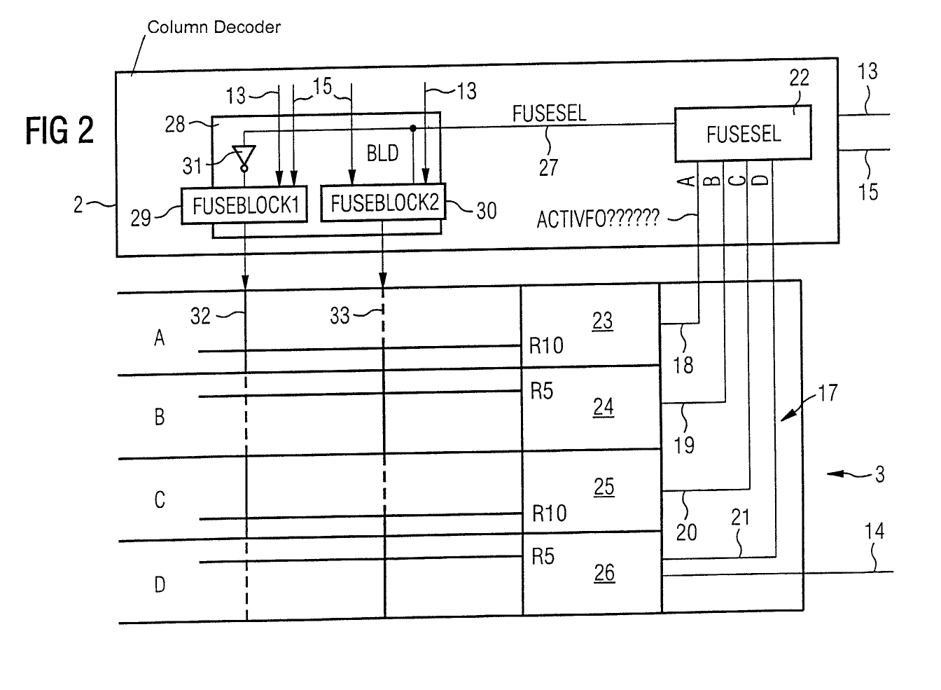

FIG. 2 shows a more precise design of the parts of the row decoder 3 and of the column decoder 2. The row decoder 3 has an evaluation circuit 17 which is connected to all of the row lines in the memory arrays 4, 5, 6, 7. The evaluation circuit 17 has, for each memory array 4, 5, 6, 7, a first data line 18, a second data line 19, a third data line 20 and a fourth data line 21 which are routed to an evaluation block 22 (fuse select) of the column decoder 2.

The evaluation circuit 17 has a first evaluation region 23, a second evaluation region 24, a third evaluation region 25 and a fourth evaluation region 26. The first evaluation region 23 is associated with the first memory array 4, the second evaluation region 24 is associated with the second memory array 5, the third evaluation region 25 is associated with the third memory array 6, and the fourth evaluation region 26 is associated with the fourth memory array 7. The first, the second, the third and the fourth evaluation regions 23, 24, 25, 26 check whether a row line in the first or the second or the third or the fourth memory array 4, 5, 6, 7 is driven by the row decoder 3. If this is the case, a signal is passed to the evaluation block 22 via the first, the second, the third or the fourth data line 18, 19, 20, 21. In this way, the evaluation block 22 ascertains whether a physical row line in the first and the third memory array 4, 6 or in the second and the fourth memory array 5, 7 is driven. If the first or the third memory array 4, 6 is driven, the evaluation block 22 outputs the logic value 1 via an output line 27. The output line 27 is routed to an evaluation circuit 28.

The selection circuit 28 has a first switching unit 29 (fuse block 1) and a second switching unit 30 (fuse block 2), to which the signal on the output line 27 is supplied. The first switching unit 29 is connected to the output line 27 via an inverter 31.

The first and the second switching unit 29, 30 are each connected to the input/output line 15.

The first switching unit 29 switches through the input/output line 15 when a High Signal, i.e. the logic value 1, is applied to the input. The second switching unit 30 switches through the input/output line 15 when a Low Signal, i.e. the logic value 0, is applied to the input.

The first and second switching units 29, 30 are each connected to the first address line 13. In the example, the circuit configuration described thus connects the input/output unit 1 to a second column line 32 when a High Signal is applied to the selection circuit 28, i.e. when the row decoder 3 has driven a row line in the first and the third memory array 4, 6. In addition, the input/output unit 1 is connected to the third column line 33 when a Low Signal is applied to the selection circuit 28, i.e. when the row decoder 3 drives a row line in the second and the fourth memory array 5, 7.

Hence, depending on which memory array is driven by the row decoder 3, various column lines 32, 33 are driven by the selection circuit 28.

This ensures a unique assignment of the physically driven column lines to the physically driven row lines. This has the advantage that, if a physical row line in the second memory array 5 is used for repairing an address in the first memory array 4, this assignment is taken into account for the selection of the column line. If the input/output unit 1 prescribes a row address which is situated in the first memory array 4, but actually a row line in the second memory array 5 is driven by the row decoder 3, then this physical assignment is taken into account for the selection of the column line by the column decoder 2.

Hence, a replacement column line addressed using the address of the repaired column line when a column line is repaired can be assigned to the first and to the second memory array 4, 6 or to the third and to the fourth memory array 6, 7 for different row addresses. Depending on which memory array contains the addressed row line, a replacement column line can also be assigned to different column addresses. The selection circuit thus assigns various column addresses to a single column line. Consequently, various column addresses are used to address the same column line.

This achieves a greater level of flexibility for repairing column lines.

Preferably, the selection circuit 28 is connected to two different replacement column lines only when the semiconductor memory is repaired. Similarly, it is preferably not until during repair that the selection circuit is stipulated such that a column line is addressed using various column addresses.

Preferably, the invention describes a method for repairing a memory configuration having a matrix memory which is subdivided into a plurality of memory arrays. The memory arrays have memory cells, where a memory cell can be accessed via a column line and a row line in order to write or read data. Each memory cell is provided with an address which includes a column address and a row address that can be used to access the memory cell. A column decoder is provided which ascertains the column line from a column address. A row decoder is provided which ascertains the row line from a prescribed row address. A column line is routed through at least two memory arrays. A faulty column line is replaced by a replacement column line by assigning the address of the replacement column line to the column address of the faulty column line in the column decoder. A selection circuit 28 is provided which connects the column decoder 2 to the replacement column line. The selection circuit 28 is connected to a first replacement column line if the row line for a driven memory cell is situated in a first memory array. The selection circuit 28 is connected to a second replacement column line if the driven row line is situated in a second memory array.

We claim:

1. A memory configuration, comprising:
a matrix memory that is subdivided into a plurality of memory arrays, said matrix memory having a plurality of column lines and a plurality of row lines, at least one of said plurality of said column lines routed through at least two of said plurality of said memory arrays, said plurality of said memory arrays having a plurality of memory cells, a respective one of said plurality of said memory cells accessible via one of said plurality of said column lines and one of said plurality of said row lines in order to write or read data, each one of said plurality of said memory cells provided with an address that can be used to access the one of said plurality of said memory cells, said address including a column address and a row address;
a column decoder for ascertaining a physical column line from the column address;
a row decoder for ascertaining a physical row line from the row address; and
an evaluation circuit connected to said plurality of said row lines, said evaluation circuit using signals that are present on said plurality of said row lines for ascertaining which one of said plurality of said memory arrays contains an addressed one of said plurality of said row lines;
said column decoder connected to said evaluation circuit;
said column decoder configured for selecting one of said plurality of said column lines by taking into account the one of said plurality of said memory arrays that contains the addressed one of said plurality of said row lines.

2. The memory configuration according to claim 1, comprising:
a selection circuit for driving different column lines based upon the one of said plurality of said memory arrays that contains the addressed one of said plurality of said row lines;
said selection circuit connected to said column decoder and to said evaluation circuit; and
said selection circuit selectable by said column decoder using a prescribed column address.

3. The memory configuration according to claim 1, comprising:
a selection circuit for driving different column lines based upon the one of said plurality of said memory arrays that contains the addressed one of said plurality of said row lines;
said selection circuit connected to said column decoder and to said evaluation circuit;
said selection circuit selectable by said column decoder using a prescribed column address; and
said selection circuit configured such that, when two different ones of said plurality of said column lines are prescribed, said selection circuit connects a single one of said plurality of said column lines to said column decoder, said selection circuit configured such that, in order to assign various column addresses to the same one of said plurality of said column lines, said selection circuit takes into account the one of said plurality of said memory arrays that contains the addressed one of said plurality of said row lines.

4. The memory configuration according to claim 1, wherein said row decoder uses a single row address to drive a respective one of said plurality of said row lines from two different ones of said plurality of said memory arrays at the same time.

5. The memory configuration according to claim 1, wherein:
said plurality of said column lines includes a plurality of replacement column lines; and
when operability of said matrix memory is checked, in order to repair two of said plurality of said column lines, said selection circuit is switched such that a connection is made to at least two of said plurality of said replacement column lines.

6. A method for repairing a memory configuration, which comprises:
providing a matrix memory that is subdivided into a plurality of memory arrays;
providing the matrix memory with a plurality of column lines and a plurality of row lines;
routing at least one of the plurality of the column lines through at least two of the plurality of the memory arrays;
providing the plurality of the memory arrays with a plurality of memory cells such that a respective one of the plurality of the memory cells is accessible via one of the plurality of the column lines and one of the plurality of the row lines in order to write or read data;
providing each one of the plurality of the memory cells with an address that can be used to access the one of the plurality of the memory cells;
providing the address with a column address and a row address;
providing a column decoder for ascertaining a physical column line from the column address;
providing a row decoder for ascertaining a physical row line from the row address;
defining one of the plurality of the column lines as a replacement column line and defining one of the plurality of the column lines as a faulty column line;
replacing the faulty column line with the replacement column line by assigning the replacement column line to the column address of the faulty column line in the column decoder;
providing a selection circuit that connects the column decoder to the replacement column line; and
configuring the selection circuit such that the replacement column line is chosen based on the one of the plurality of the row lines that is associated with the one of the plurality of the memory cells that is repaired by the replacement column line.

7. The method according to claim 6, which comprises: configuring the selection circuit such that, with different column addresses, the selection circuit connects the column decoder to the replacement column line if the row addresses associated with the different column addresses point to ones of the plurality of the row lines that are situated in different ones of the plurality of the memory arrays.

8. The method according to claim 6, which comprises: configuring the selection circuit such that, for the same column address, the selection circuit connects the column decoder to various replacement ones of the plurality of the column lines if the row addresses associated with the column addresses point to ones of the plurality of the row lines which are situated in different ones of the plurality of the memory arrays.
